(19) United States
(12) Patent Application Publication
(10) Pub. No.: US 2023/0378392 A1
(43) Pub. Date: Nov. 23, 2023

(54) PARTICLE ALIGNMENT DEVICE AND METHOD FOR MICRO LED DISPLAY, AND MICRO LED DISPLAY

(71) Applicant: SEMES CO., LTD., Chungcheongnam-do (KR)

(72) Inventors: In Ho KIM, Chungcheongnam-do (KR); Jae Youl KIM, Chungcheongnam-do (KR); Cheol Yong SHIN, Chungcheongnam-do (KR); Jin Woo JANG, Chungcheongnam-do (KR)

(21) Appl. No.: 18/099,914

(22) Filed: Jan. 20, 2023

(30) Foreign Application Priority Data
May 19, 2022 (KR) 10-2022-0061192

(51) Int. Cl. H01L 33/00; H01L 25/075; H01L 33/20

(52) U.S. Cl. CPC H01L 33/005; H01L 25/0753; H01L 33/20

(57) ABSTRACT

A particle alignment device for a micro LED display, the particle alignment device includes a glass electrode arranged on one surface of the glass substrate on which a pattern is formed, a gripper supporting a glass substrate, the gripper including a gripper electrode interposed between the glass substrate and the gripper, a resistance unit connecting the glass electrode, and an AC signal generator connected to the gripper electrode to generate an AC signal. The glass electrode and the gripper electrode are arranged to oppose each other with the glass substrate interposed therebetween.

### CROSS-REFERENCE TO RELATED APPLICATION(S)

This application claims benefit of priority to Korean Patent Application No. 10-2022-0061192 filed on May 19, 2022 in the Korean Intellectual Property Office, the disclosure of which is incorporated herein by reference in its entirety.

### BACKGROUND

### 1. Field

The present disclosure relates to a particle alignment device and method for a micro LED display, and a micro LED display.

### 2. Description of Related Art

When nanomaterials are melted on a surface having a specific pattern, the nanomaterials are separated into liquid droplets. In this case, using a phenomenon in which nano liquid droplets align themselves in a specific direction, highly uniform and aligned nanowires may be formed, and it is essential to perform alignment of particles such as nanowires in organic semiconductors.

In the related art, in order to align particles by supplying power to a glass substrate to which an electrode is attached, the glass substrate is seated on the gripper, and then control needs to be performed so as to bring a power supply line supplying power into contact with the electrode of the glass substrate such that positions of the power supply line and the electrode of the glass substrate correspond to each other. That is, in order for the positions of the power supply line and the electrode of the glass substrate to correspond to each other, the glass substrate may be seated depending on the position of the power supply line, or a direct contact method may be used in which the position of the power supply line is controlled depending on the position of the glass substrate to cause direct contact between the electrode of the glass substrate and the power supply line.

In other words, when it is necessary to supply power to a glass pattern in a process of manufacturing a semiconductor, power is supplied through an electrode positioned on an edge of the glass substrate. When contact between the power supply line and the electrode of the glass substrate is perfect, power may be supplied without power loss. In the process of connecting a glass electrode, a process of checking connection between the electrodes and the power supply line needs to be performed. As a result, additional processing time is required, and thus the total processing time is increased.

Accordingly, in order to resolve the issue of the related art, there is a need for a device and method for aligning particles of a glass substrate through non-contact power transmission.

### SUMMARY

An aspect of the present disclosure provides a particle alignment device and method for a micro LED display allowing particle alignment to be performed through power supply without position control by seating a glass substrate on a gripper and supplying AC power at the same time, and a micro LED display.

According to an aspect of the present disclosure, there is provided a particle alignment device for a micro LED display, the particle alignment device including a glass electrode arranged on one surface of the glass substrate on which a pattern is formed, a gripper supporting a glass substrate, the gripper including a gripper electrode interposed between the glass substrate and the gripper, a resistance unit connecting the glass electrode, and an AC signal generator connected to the gripper electrode to generate an AC signal. The glass electrode and the gripper electrode may be arranged to oppose each other with the glass substrate interposed therebetween.

According to another aspect of the present disclosure, there is provided a micro LED display including a glass substrate on which a particle molecule oriented in a predetermined direction is arranged by the above-described particle alignment device.

According to another aspect of the present disclosure, there is provided a particle alignment method for a micro LED display, the method including seating, on a gripper, a glass substrate on which a pattern is formed, the glass substrate having one surface on which a glass electrode is arranged, arranging the glass electrode and the gripper electrode arranged on an upper portion of the gripper to oppose each other with the glass substrate interposed therebetween, and aligning particles of the glass substrate by generating an AC signal and supplying power to the gripper electrode.

According to example embodiments of the present disclosure, a process of being in direct contact with a power supply line may be omitted, and non-contact power supply may be performed only by seating a glass substrate on a gripper, thereby reducing overall processing time and simplifying a process.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a front view illustrating a configuration of a particle alignment device for a micro LED display according to an example embodiment of the present disclosure;

FIG. 2 is a schematic side perspective view illustrating a configuration of a particle alignment device for a micro LED display according to an example embodiment of the present disclosure;

FIG. 3 illustrates an arrangement relationship between a glass electrode and a gripper electrode according to an example embodiment of the present disclosure;

FIG. 4 illustrates an arrangement relationship between a glass electrode and a gripper electrode according to an example embodiment of the present disclosure;

FIG. 5 illustrates an arrangement relationship between a glass electrode and a gripper electrode according to an example embodiment of the present disclosure;

FIG. 6 illustrates an arrangement relationship between a glass electrode and a gripper electrode according to an example embodiment of the present disclosure;

FIG. 7 illustrates an arrangement relationship between a glass electrode and a gripper electrode according to an example embodiment of the present disclosure;

FIG. 8 illustrates a particle alignment device in which a glass electrode, a gripper electrode, and a glass substrate have different thicknesses according to an example embodiment of the present disclosure;

FIG. 9 illustrates a circuit diagram of a particle alignment device according to an example embodiment of the present disclosure;

FIGS. 10A and 10B illustrate a configuration of a particle alignment device according to another example embodiment of the present disclosure; and

FIG. 11 illustrates a flowchart of a particle alignment method for a micro LED display according to an example embodiment of the present disclosure.

### DETAILED DESCRIPTION

Hereinafter, preferred example embodiments will be described in detail, such that the invention could be easily carried out. In describing example embodiments of the present disclosure, when it is determined that a detailed description of a known technology related to the present disclosure may unnecessarily obscure the gist of the present disclosure, the detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, steps, operations, elements, components or a combination thereof, but do not preclude the presence or addition of one or more other features, integers, steps, operations, elements, components, and/or groups thereof.

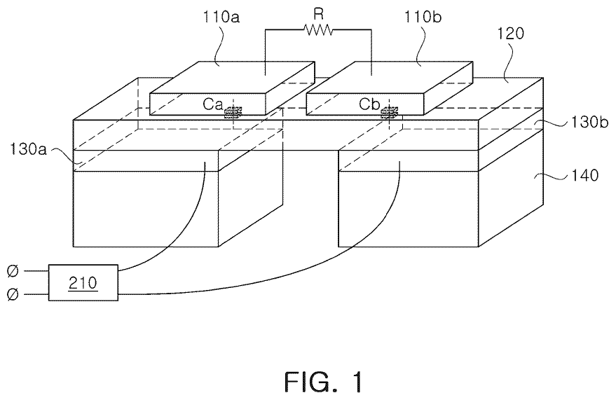

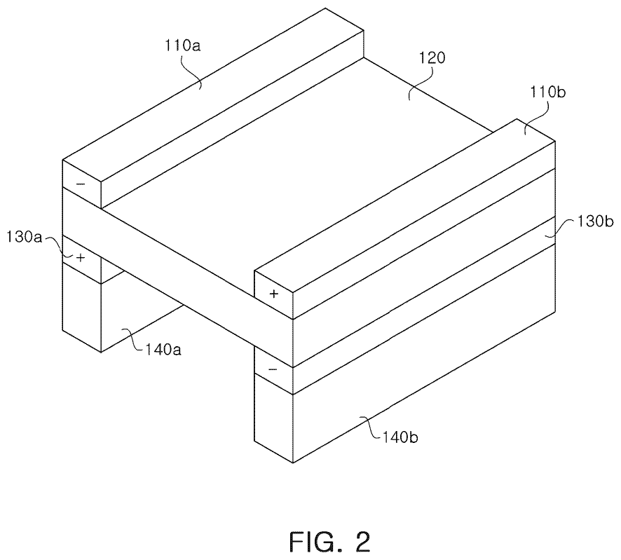

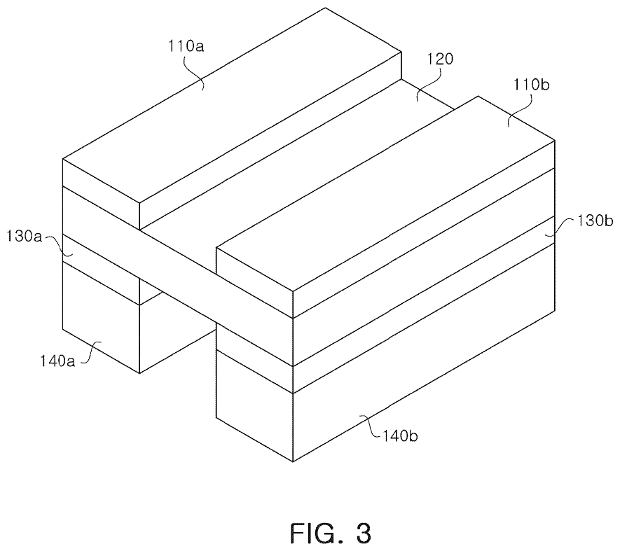

FIGS. 1 and 2 schematically illustrate a configuration of a particle alignment device for a micro LED display according to an example embodiment of the present disclosure, and FIGS. 3 to 7 illustrate a specific example embodiment of a particle alignment device according to an example embodiment of the present disclosure.

As illustrated in FIG. 1, a particle alignment device for a micro LED display according to an example embodiment of the present disclosure may include glass electrodes 110a and 110b arranged on one surface of a glass substrate 120 on which a pattern is formed, a gripper 140 supporting the glass substrate 120, the gripper 140 including gripper electrodes 130a and 130b interposed between the glass substrate 120 and the gripper 140, and an AC signal generator 210 connected to the gripper electrodes 130a and 130b to generate an AC signal. The glass electrodes 110a and 110b and the gripper electrodes 130a and 130b may be arranged to oppose each other with the glass substrate 120 interposed therebetween.

In this case, the glass electrodes 110a and 110b and the gripper electrodes 130a and 130b may have a specific polarity due to power supplied by the AC signal generator 210. For example, as illustrated in FIG. 2, the glass electrode 110a may have a cathode, and the gripper electrode 130a may have an anode. The glass electrode 110b may have an anode, and the gripper electrode 130b may have a cathode.

The glass electrodes 110a and 110b and the gripper electrodes 130a and 130b may be arranged to oppose each other through the glass substrate 120, such that the glass substrate 120 interposed between the glass electrodes 110a and 110b and the gripper electrodes 130a and 130b may receive power as a capacitive impedance. That is, the glass substrate 120 may transmit power as a capacitor. An electrode may serve as an electrode plate of a capacitor, and a glass substrate may serve as an insulator of a capacitor.

The glass substrate 120 may function as a capacitor. Thus, even when no power supply line is connected, AC power of the AC signal generator 210 connected to the gripper electrodes 130a and 130b may be transmitted to the glass electrodes 110a and 110b through the glass substrate 120.

Power may be supplied by arranging a receiving electrode to be close to a transmitting electrode without direct contact between the glass electrodes 110a and 110b serving as the receiving electrode and the gripper electrodes 130a and 130b serving as the transmitting electrode. Accordingly, mechanical contact or electrical contact may not be required to supply power for aligning particles of the glass substrate 120. The AC signal generator 210 provided with a driver may output an AC voltage signal having a variable frequency to a circuit having a series capacitor.

In addition, as illustrated in FIG. 1, a resistor R may be connected between the glass electrodes 110a and 110b. In an example embodiment, an arbitrary variable resistor may be connected between the glass electrodes 110a and 110b, through which a potential difference between the glass electrodes 110a and 110b may be generated to generate a desired electric field with respect to the glass substrate 120.

In this case, in an example embodiment, as illustrated in FIG. 2, the glass electrodes 110a and 110b may be spaced apart from opposite ends of the one surface of the glass substrate 120. The gripper electrodes 130a and 130b may also be spaced apart from opposite ends of the grippers 140a and 140b.

In addition, the glass electrode 110a and the gripper electrode 130a arranged to oppose each other may have different polarities. For example, the glass electrode 110a may have a cathode (−) and the gripper electrode 130a may have an anode (+), and the other glass electrode 110b may have an anode (+) and the other gripper electrode 130b may have a cathode (−).

As illustrated in FIG. 2, the gripper 140 according to an example embodiment of the present disclosure may include a first gripper 140a supporting a first side surface of the glass substrate 120 and a second gripper 140b supporting a second side surface of the glass substrate 120. In this case, the gripper 140 may include the gripper electrode 130a having an area occupying an entire upper portion of the first gripper 140a, and the gripper electrode 130b having an area occupying the entire upper portion of the second gripper 140b, rather than the gripper electrode 130a and the gripper electrode 130b being spaced from opposite ends of the gripper 140.

In addition, at least one of the gripper electrodes 130a and 130b may be arranged on an upper portion of the first gripper 140a, and the other one of the gripper electrodes 130a and 130b may be arranged on an upper portion of the second gripper 140b. For example, as illustrated in FIG. 2, an anode electrode may be arranged on the first gripper 140a and a cathode electrode may be arranged on the second gripper 140b, and the glass electrodes 110a and 110b having different polarities may be arranged to oppose the gripper electrodes 130a and 130b through the glass substrate 120.

Accordingly, at the same time, the glass substrate 120 may be seated on the gripper 140, and the glass electrodes 110a and 110b and the gripper electrodes 130a and 130b may be arranged to oppose each other with the glass substrate 120 interposed therebetween. Hereinafter, a connection relationship between the glass electrodes 110a and 110b and the gripper electrodes 130a and 130b will be described with reference to FIGS. 3 to 7.

As illustrated in FIG. 3, in the particle alignment device for a micro LED display according to an example embodiment of the present disclosure, the glass electrodes 110a and 110b and the gripper electrodes 130a and 130b may be arranged to oppose each other such that one electrode among the glass electrodes 110a and 110b and the gripper electrodes 130a and 130b overlaps an entire area of the other electrode.

Referring to FIG. 3, the gripper electrodes 130a and 130b may be arranged to fill areas of entire upper portions of grippers 140a and 140b, and glass electrodes 110a and 110b may be arranged at opposite ends of the glass substrate 120. The gripper electrodes 130a and 130b and the glass electrodes 110a and 110b may be arranged to oppose each other exactly such that the entire areas of the gripper electrodes 130a and 130b and the glass electrodes 110a and 110b overlap each other.

Power may be received through the entire areas of the gripper electrodes 130a and 130b and the glass electrodes 110a and 110b, such that particles may be aligned according to stronger power.

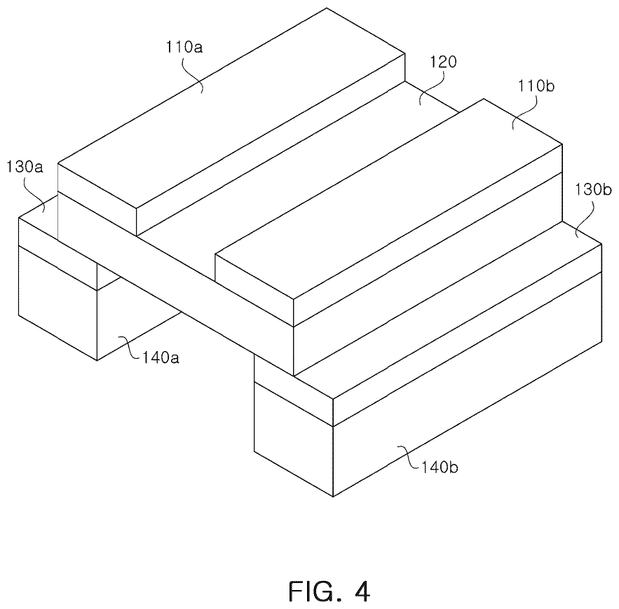

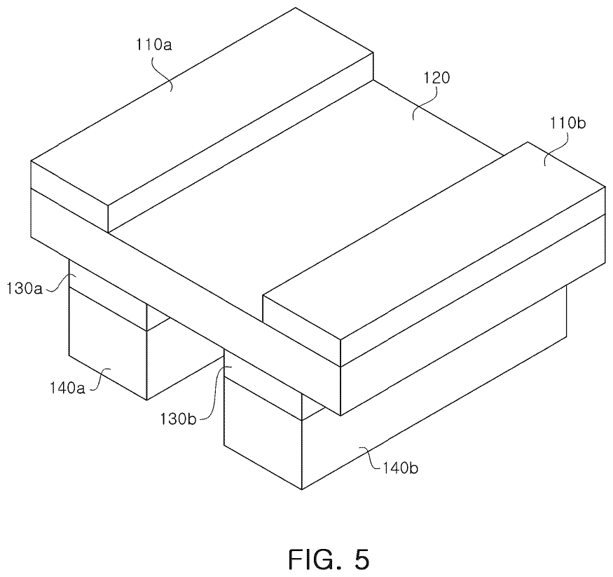

Alternatively, as illustrated in FIGS. 4 and 5, in the particle alignment device for a micro LED display according to an example embodiment of the present disclosure, the glass electrodes 110a and 110b and the gripper electrodes 130a and 130b may be arranged to oppose each other such that the glass electrodes 110a and 110b and the gripper electrodes 130a and 130b having different polarities overlap each other in terms of at least a partial area.

As illustrated in FIG. 3, in order to allow the entire areas, precise position control may be required in a similar manner to a direct contact method, such that additional processing time may be required for position control. Accordingly, the partial areas may be arranged to overlap each other without precise position control, such that a capacitance of the glass substrate 120 may be formed, and particle alignment may be performed through transmission and reception of power.

Specifically, as illustrated in FIGS. 4 and 5, when the glass substrate 120 is seated on the grippers 140a and 140b by arranging the gripper electrodes 130a and 130b to fill the areas of the entire upper portions of the grippers 140a and 140b, and arranging the glass electrodes 110a and 110b at the opposite ends of the glass substrate 120, the gripper electrodes 130a and 130b and the glass electrodes 110a and 110b may be essentially arranged to oppose each other.

In the above-described arrangement, even when an area of the glass substrate 120 is smaller than a space between the grippers 140a and 140b as illustrated in FIG. 4, or the area of the glass substrate 120 is larger than the space between the grippers 140a and 140b as illustrated in FIG. 5, the glass electrodes 110a and 110b and the gripper electrodes 130a and 130b may be arranged to oppose each other, such that the glass substrate 120 may operate as a capacitive impedance.

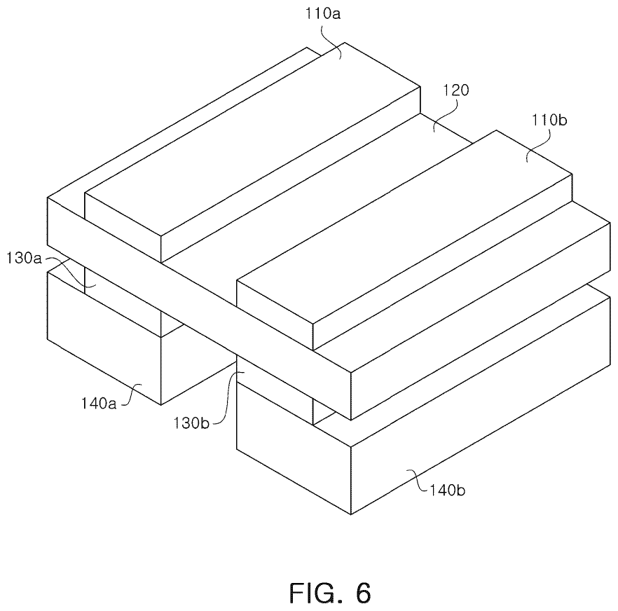

As illustrated in FIG. 6, in the particle alignment device for a micro LED display according to an example embodiment of the present disclosure, when the gripper electrodes 130a and 130b are arranged in partial areas of the grippers 140a and 140b without filling the areas of the entire upper portions of the grippers 140a and 140b, the gripper electrodes 130a and 130b may be arranged at near opposite ends of the grippers 140a and 140b rather than at far opposite ends of the grippers 140a and 140b.

In this case, the glass electrodes 110a and 110b may also be arranged in an off-center middle region of the glass substrate 120 rather than at the opposite ends of the glass substrate 120.

As illustrated in FIG. 6, a larger area of the glass substrate 120 may overlap the inside of the grippers 140a and 140b, rather than the outside of the grippers 140a and 140b. Accordingly, even when the glass substrate 120 is not arranged in a correct position, the gripper electrodes 130a and 130b may be arranged at opposite inner ends of the grippers 140a and 140b such that a larger area of the glass substrate 120 overlaps the grippers 140a and 140b when seated on the grippers 140a and 140b.

The glass electrodes 110a and 110b may also be arranged in a middle region of the glass substrate 120 rather than at the opposite ends of the glass substrate 120 so as to increase an overlapping area.

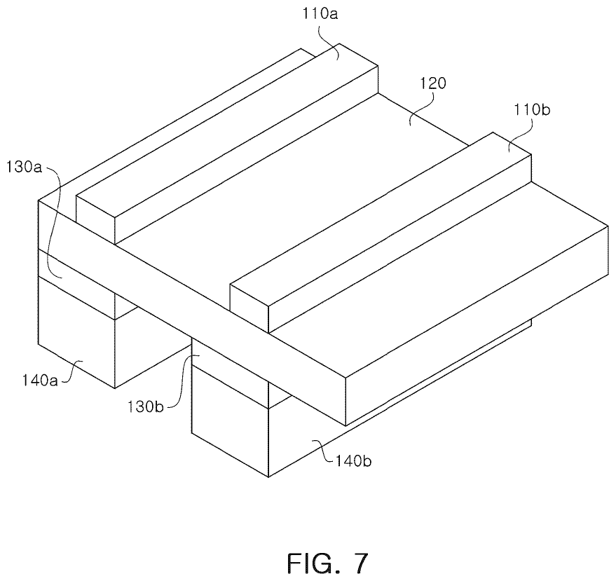

In addition, as illustrated in FIG. 7, the glass electrodes 110a and 110b and the gripper electrodes 130a and 130b may be arranged to oppose each other such that the entire areas of the glass electrodes 110a and 110b and the gripper electrodes 130a and 130b having the same polarity overlap each other. When the areas of the glass electrodes 110a and 110b is smaller than the areas of the gripper electrodes 130a and 130b, as illustrated in FIG. 7, the glass electrodes 110a and 110b may be arranged to be included in the gripper electrodes 130a and 130b with the glass substrate 120 therebetween.

In another example embodiment, the areas of the glass electrodes 110a and 110b may be larger than the areas of the gripper electrodes 130a and 130b.

For example, as an overlapping area between the glass electrodes 110a and 110b and the gripper electrodes 130a and 130b increases, stronger power may be transmitted and received. In order to increase the overlapping area and omit precise position control, the gripper electrodes 130a and 130b may be arranged such that the areas of the gripper electrodes 130a and 130b are equal to or greater than the areas of the upper portions of the grippers 140a and 140b, and the glass electrodes 110a and 110b may be arranged in the middle region or the opposite ends of the glass substrate 120 such that the areas of the glass electrodes 110a and 110b are larger than the areas of the gripper electrodes 130a and 130b, the overlapping area may be increased, thereby strongly performing transmission and reception of power.

According to an example embodiment of the present disclosure, the glass electrodes 110a and 110b may be transparent electrodes separated from the interior of the glass substrate 120. That is, the glass substrate 120, a transparent insulator, and the glass electrodes 110a, 110b, transparent conductors, may be arranged in a manner of being separated from the interior thereof.

The glass electrodes 110a and 110b or the gripper electrodes 130a and 130b may have any shape including, for example, a rectangular shape, a circular shape, a square shape, or combinations thereof. Each of the gripper electrodes 130a and 130b may be a conductive material, for example, carbon, aluminum, indium tin oxide (ITO), an organic material (for example, PEDOT), copper, silver, conductive paint, or any conductive material. A total capacitance of the particle alignment device may be formed by an overlapping area of each of the glass electrodes 110a and 110b and the gripper electrodes 130a and 130b and a thickness and material properties of the glass substrate 120.

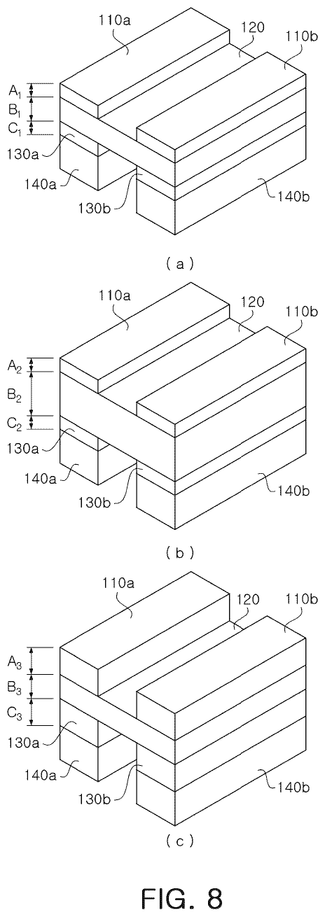

FIG. 8 illustrates a particle alignment device in which the glass electrodes 110a and 110b, the gripper electrodes 130a and 130b, and the glass substrate 120 have different thicknesses according to an example embodiment of the present disclosure.

Specifically, as illustrated in FIG. 8, a thickness B1 of the glass substrate 120 in FIG. 8A may be less than a thickness B2 of the glass substrate 120 in FIG. 8B. In this case, a capacitance of the glass substrate 120 in FIG. 8A may be less than a capacitance of the glass substrate 120 in FIG. 8B, such that the glass substrate 120 in FIG. 8A may transmit power more rapidly, thereby rapidly performing particle alignment. In order to rapidly perform particle alignment, the thickness of the glass substrate 120 may be reduced.

In addition, a thickness A1 of each of the glass electrodes 110a and 110b or a thickness C1 of each of the gripper electrodes 130a and 130b in FIG. 8A may be less than a thickness A3 of each of the glass electrodes 110a and 110b or a thickness C3 of each of the gripper electrodes 130a and 130b in FIG. 8C. As a thickness of an electrode increases, more power may be supplied, such that particle alignment may be rapidly performed. Accordingly, as described above, the overlapping area between the glass electrodes 110a and 110b and the gripper electrodes 130a and 130b may be increased, and the thicknesses of the glass electrodes 110a and 110b and the gripper electrodes 130a and 130b may be increased, thereby rapidly performing particle alignment.

Accordingly, according to an example embodiment of the present disclosure, when power is supplied through the AC signal generator 210 connected to the gripper electrodes 130a and 130b, the gripper electrodes 130a and 130b and the glass electrodes 110a and 110b may receive power through the gripper electrodes 130a and 130b, the glass substrate 120, and the glass electrodes 110a and 110b, using a field effect type electric field.

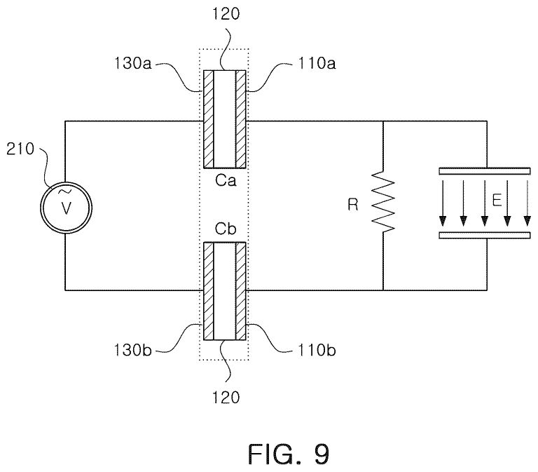

FIG. 9 is an equivalent circuit diagram of a particle alignment device according to an example embodiment of the present disclosure, and the above-described particle alignment device may be formed as the circuit illustrated in FIG. 9. When the gripper electrodes 130a and 130b and the glass electrodes 110a and 110b are arranged to oppose each other, the gripper electrodes 130a and 130b and the glass electrodes 110a and 110b, and the glass substrate 120 used as a dielectric between the gripper electrodes 130a and 130b and the glass electrodes 110a and 110b may form capacitors Ca and Cb.

In addition, a resistor R may be connected between the capacitors Ca and Cb to form a single circuit, and the resistor R may be arranged to form a completed circuit. In addition, the resistor R may generate a potential difference between the two capacitors Ca and Cb to supply an electric field to a region in which a process is performed.

In another example embodiment, particles of a micro LED display may be aligned by applying the electric field to the process. That is, a resistor unit including the resistor R may be connected to the glass electrodes 110a and 110b so as to complete a closed circuit and provide the electric field to the glass substrate 120.

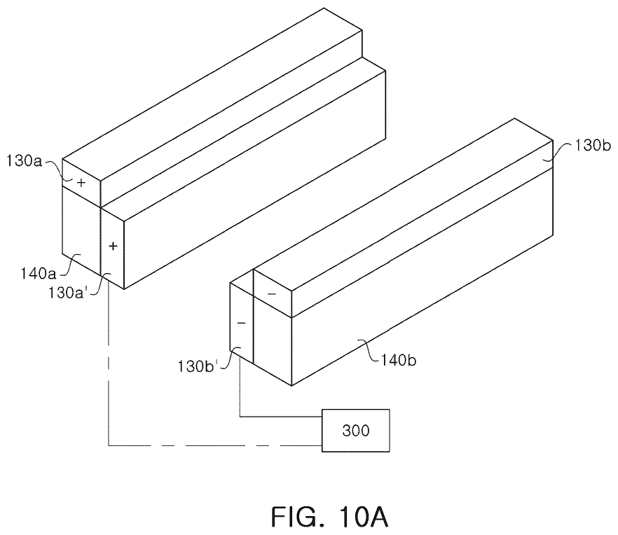

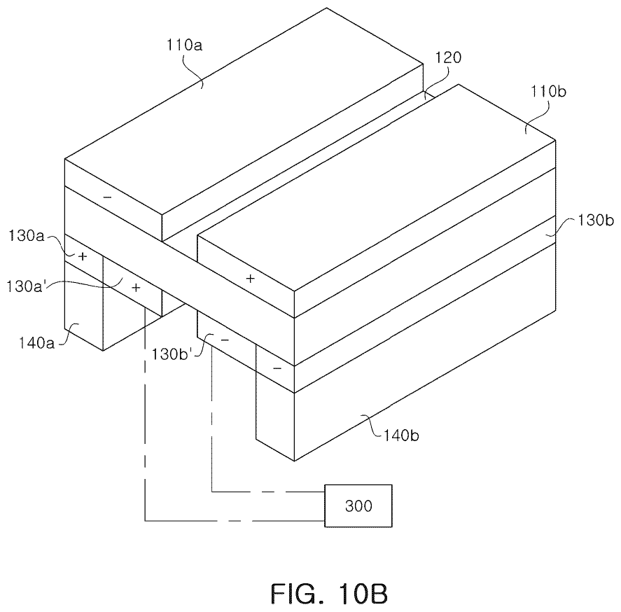

FIGS. 10A and 10B illustrate a configuration of a particle alignment device according to another example embodiment of the present disclosure.

According to an example embodiment of the present disclosure, an additional electrode connected to one side of the gripper 140 may be included. When the gripper 140 supports the glass substrate 120, a driver 300, moving the additional electrode to one side of each of the gripper electrodes 130a and 130b, may be included to expand areas of the gripper electrodes 130a and 130b.

An area of an upper portion of the gripper 140 may be limited. In order to increase an overlapping area, the gripper electrodes 130a and 130b may be arranged on the upper portion of the gripper 140, and an additional gripper electrode may be arranged on the one side of the gripper 140, such that, whenever the glass substrate 120 is seated, the additional gripper electrode may be connected to sides of the gripper electrodes 130a and 130b to expand areas of the gripper electrode 130a or 130b.

As illustrated in FIG. 10A, the gripper electrode 130a may be positioned on an upper portion of the first gripper 140a, and an additional gripper electrode 130a′ may be positioned on a side surface of the first gripper 140a. Before the glass substrate 120 is seated, the additional gripper electrode 130a′ may be arranged on one side of the first gripper 140a for space utilization without being connected to the gripper electrode 130a.

In addition, the gripper electrode 130b may be positioned on an upper portion of the second gripper 140b, and an additional gripper electrode 130b′ may be positioned on a side surface of the second gripper 140b. Before the glass substrate 120 is seated, the additional gripper electrode 130b′ may be arranged on one side of the second gripper 140b without being connected to the gripper electrode 130b.

As illustrated in FIG. 10B, when the glass substrate 120 is seated on the grippers 140a and 140b, the additional gripper electrodes 130a′ and 130b′ may rotate to increase areas of the gripper electrodes 130a and 130b opposing the glass electrodes 110a and 110b. An area in which all the gripper electrodes 130a, 130a′, 130b, and 130b′ and the glass electrodes 110a and 110b oppose each other may be increased to increase a capacitance. When the capacitance increases, loss caused by leakage current may be reduced to increase a potential difference across the resistor R, thereby improving AC power efficiency.

In an example embodiment, the driver 300, connected to the additional gripper electrodes 130a′ and 130b′, may adjust positions of the additional gripper electrodes 130a′ and 130b′ depending on whether the glass substrate 120 is seated on the gripper 140.

When a process is completed, the state illustrated in FIG. 10B may return to the state illustrated in FIG. 10A, and thus a state of the additional gripper electrodes 130a′ and 130b′ may return back to be a state in which the additional gripper electrodes 130a′ and 130b′ are in contact with side surfaces of the grippers 140a and 140b.

Accordingly, the particle alignment device according to an example embodiment of the present disclosure may transmit power over a large area.

In addition, the particle alignment device according to an example embodiment of the present disclosure may include the AC signal generator 210 provided with a driver connected to the gripper electrodes 130a and 130b, and a frequency of the AC signal generator 210 may be adjusted to generate a modulated control signal. The driver may generate a control signal being modulated with respect to an AC power signal, and may change a frequency and/or power of an AC signal output based on feedback.

That is, the particle alignment device according to an example embodiment of the present disclosure may supply power immediately when the glass substrate 120 is seated on the gripper 140, thereby overall processing time.

It is possible to provide a micro LED display including the glass substrate 120 on which particle molecules oriented in a predetermined direction are arranged by the above-described particle alignment device for a micro LED display.

Particle alignment may be completed, and the glass electrodes 110a and 110b may be removed from the glass substrate 120, such that the glass substrate 120 from which the glass electrodes 110a and 110b are removed may be used for the micro LED display.

In FIG. 9, it is illustrated that the capacitors Ca and Cb, the resistor R, and an electric field E are formed in parallel. However, actually, the resistor R, and the electric field E may be arranged on an upper portion of the glass substrate 120 functioning as the capacitors Ca and Cb, and the formed electric field E may act on the glass substrate 120 to align and fix nanowires to perform particle arrangement.

That is, the electric field formed on the glass substrate 120 may mean that the glass substrate 120 operating as the capacitors Ca and Cb is arranged under the influence of the electric field.

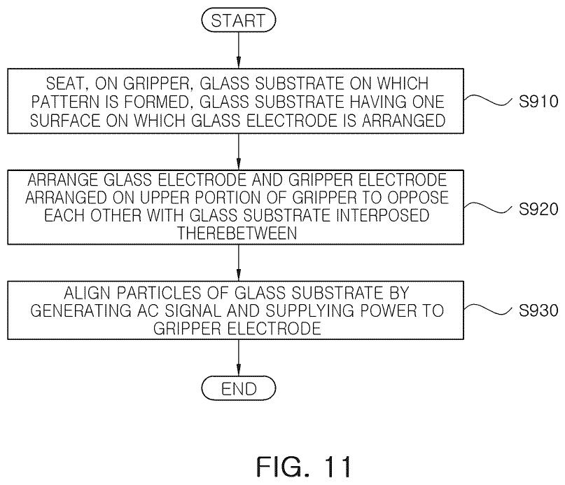

FIG. 11 illustrates a flowchart of a particle alignment method for a micro LED display according to an example embodiment of the present disclosure.

As illustrated in FIG. 11, in the particle alignment method for a micro LED display according to an example embodiment of the present disclosure may include seating, on the gripper 140, the glass substrate 120 on which a pattern is formed, the glass substrate 120 having one surface on which the glass electrodes 110a and 110b are arranged (S910), arranging the glass electrodes 110a and 110b and the gripper electrodes 130a and 130b arranged on an upper portion of the gripper 140 to oppose each other with the glass substrate 120 interposed therebetween (S920), and aligning particles of the glass substrate 120 by generating an AC signal and supplying power to the gripper electrodes 130a and 130b (S930).

In addition, when power is supplied through the AC signal generator 210 connected to the gripper electrodes 130a and 130b, the gripper electrodes 130a and 130b and the glass electrodes 110a and 110b may receive power through the gripper electrodes 130a and 130b, the glass substrate 120, and the glass electrodes 110a and 110b, using a field effect type electric field.

In addition, the arranging the glass electrodes 110a and 110b and the gripper electrodes 130a and 130b arranged the upper portion of the gripper 140 to oppose each other with the glass substrate 120 interposed therebetween (S920) may include at least one of arranging the glass electrodes 110a and 110b and the gripper electrodes 130a and 130b to oppose each other such at least partial areas of the glass electrodes 110a and 110b and the gripper electrodes 130a and 130b having the same polarity overlap each other, arranging the glass electrodes 110a and 110b and the gripper electrodes 130a and 130b to oppose each other such that one electrode among the glass electrodes 110a and 110b and the gripper electrodes 130a and 130b overlaps an entire area of the other electrode, and arranging the glass electrodes 110a and 110b and the gripper electrodes 130a and 130b such that entire areas of the glass electrodes 110a and 110b and the gripper electrodes 130a and 130b having the same polarity overlap each other.

Accordingly, the glass electrodes 110a and 110b and the gripper electrodes 130a and 130b may be arranged to oppose each other. As an overlapping region between the glass electrodes 110a and 110b and the gripper electrodes 130a and 130b increases, particle alignment may be smoothly performed.

In addition, the glass electrodes 110a and 110b and the gripper electrodes 130a and 130b arranged on the upper portion the gripper 140 oppose each other with the glass substrate 120 interposed therebetween (S920) may further include moving an additional electrode, connected to one side of the gripper 140, to one side of each of the gripper electrodes 130a and 130b such that an area of each of the gripper electrodes 130a and 130b is expanded when the glass substrate 120 is seated on the gripper 140.

For example, the additional electrode may be horizontally arranged next to the gripper electrodes 130a and 130b by rotating the additional electrode vertically arranged on the one side of the gripper 140, thereby expanding electrode areas of the gripper electrodes 130a and 130b. When the electrode area is expanded, more power may be transmitted and received, thereby performing particle alignment more rapidly.

In addition, the glass substrate 120 interposed between the glass electrodes 110a and 110b and the gripper electrodes 130a and 130b may charge power as a capacitive impedance, and a capacitance may be formed depending on a thickness of the glass substrate 120 interposed between the glass electrodes 110a and 110b and the gripper electrodes 130a and 130b. Transmission and reception of power may be rapidly performed by reducing the thickness of the glass substrate 120.

Accordingly, when alignment of particles of the glass substrate 120 is completed, the glass electrodes 110a and 110b of the glass substrate 120 may be removed, such that the glass substrate 120 on which the particle alignment is completed may be used as the micro LED display.

The particle alignment device according to an example embodiment of the present disclosure may include a bottom transparent non-conductive layer, an upper transparent non-conductive layer, and a transparent conductive layer therebetween, and the conductive layer may be arranged in a manner of forming a pair of transmitting electrodes attached to the upper non-conductive layer. The receiving electrode may be formed of a conductive material the same as that of a middle conductive layer. A conductive material of the transmitting electrode may be transparent or translucent. Such a material may be transparent or translucent when arranged in a very thin layer. For example, ITO may be already transparent by nature thereof, for example, may be more than 95% transparent regardless of an electrode thickness.

In addition, in describing the present disclosure, a component performing control may be implemented by various methods, for example, a processor, program instructions executed by the processor, a software module, a microcode, a computer program product, a logic circuit, an application-specific integrated circuit, firmware, and the like.

The method described in the example embodiments of the present application may be directly implemented by a hardware processor, or may be implemented by a hardware module and a software module among processors. The software module may be stored in a conventional storage medium such as random access memory, flash memory, read only memory, programmable read only memory or electrically erasable programmable memory, a register, or the like. The storage medium is positioned in the memory, and the processor reads information stored in the memory to combine the information with the hardware to complete the above-described method. To avoid duplication, a detailed description will be omitted herein.

While example embodiments have been shown and described above, it will be apparent to those skilled in the art that modifications and variations could be made without departing from the scope of the present disclosure as defined by the appended claims.

What is claimed is:

1. A particle alignment device for a micro LED display, the particle alignment device comprising:
a glass electrode arranged on one surface of the glass substrate on which a pattern is formed;
a gripper supporting a glass substrate, the gripper including a gripper electrode interposed between the glass substrate and the gripper;
a resistance unit connecting the glass electrode; and
an AC signal generator connected to the gripper electrode to generate an AC signal,
wherein the glass electrode and the gripper electrode are arranged to oppose each other with the glass substrate interposed therebetween.

2. The particle alignment device of claim 1, wherein the glass electrode and the gripper electrode are arranged to oppose each other such that the glass electrodes and the gripper electrodes having different polarities overlap each other in terms of at least a partial area.

3. The particle alignment device of claim 1, wherein the glass electrode and the gripper electrode are arranged to oppose each other such that one electrode among the glass electrode and the gripper electrode overlaps an entire area of the other electrode.

4. The particle alignment device of claim 3, wherein the glass electrode and the gripper electrode are arranged to oppose each other such that entire areas of the glass electrode and the gripper electrode having different polarities overlap each other.

5. The particle alignment device of claim 1, wherein
the glass electrode is spaced apart from opposite ends of the one surface of the glass substrate, and
the gripper electrode is spaced apart from opposite ends of the gripper.

6. The particle alignment device of claim 5, wherein
the gripper includes a first gripper supporting a first side surface of the glass substrate and a second gripper supporting a second side surface of the glass substrate, and
at least one of the gripper electrodes is arranged on an upper portion of the first gripper, and another one of the gripper electrodes is arranged on an upper portion of the second gripper.

7. The particle alignment device of claim 1, wherein, when power is supplied through the AC signal generator connected to the gripper electrode, the gripper electrode and the glass electrode receive power through the gripper electrode, the glass substrate, and the glass electrode, using a field effect type electric field.

8. The particle alignment device of claim 1, wherein an area of the glass electrode is larger than an area of the gripper electrode.

9. The particle alignment device of claim 1, wherein the glass electrode is a transparent electrode separated from an interior of the glass substrate.

10. The particle alignment device of claim 1, comprising:
an additional electrode connected to one side of the gripper; and
a driver moving the additional electrode to one side of the gripper electrode such that an area of the gripper electrode is expanded when the gripper supports the glass substrate.

11. The particle alignment device of claim 1, wherein the glass substrate interposed between the glass electrode and the gripper electrode receives power as a capacitive impedance.

12. A micro LED display comprising:
a glass substrate on which a particle molecule oriented in a predetermined direction is arranged by a particle alignment device according to claim 1.

13. A particle alignment method for a micro LED display, the method comprising:
seating, on a gripper, a glass substrate on which a pattern is formed, the glass substrate having one surface on which a glass electrode is arranged;
arranging the glass electrode and the gripper electrode arranged on an upper portion of the gripper to oppose each other with the glass substrate interposed therebetween; and
aligning particles of the glass substrate by generating an AC signal and supplying power to the gripper electrode.

14. The method of claim 13, wherein, when power is supplied through the AC signal generator connected to the gripper electrode, the gripper electrode and the glass electrode receive power through the gripper electrode, the glass substrate, and the glass electrode, using a field effect type electric field.

15. The method of claim 13, wherein the arranging the glass electrode and the gripper electrode arranged on the upper portion of the gripper to oppose each other with the glass substrate interposed therebetween further includes:
moving an additional electrode, connected to one side of the gripper, to one side of the gripper electrode such that an area of the gripper electrode is expanded when the glass substrate is seated on the gripper.

16. The method of claim 15, wherein the moving the additional electrode to the one side of the gripper electrode includes:
horizontally arranging the additional electrode next to the gripper electrode by rotating the additional electrode vertically arranged on the one side of the gripper.

17. The method of claim 14, wherein the glass substrate interposed between the glass electrode and the gripper electrode charges power as a capacitive impedance.

18. The method of claim 17, wherein a capacitance is formed depending on a thickness of the glass substrate interposed between the glass electrode and the gripper electrode.

19. The method of claim 13, further comprising:
removing the glass electrode of the glass substrate when alignment of the particles of the glass substrate is completed.

20. The method of claim 13, wherein the arranging the glass electrode and the gripper electrode arranged the upper portion of the gripper to oppose each other with the glass substrate interposed therebetween includes at least one of:
arranging the glass electrode and the gripper electrode to oppose each other such at least partial areas of the glass electrode and the gripper electrode having the same polarity overlap each other;
arranging the glass electrode and the gripper electrode to oppose each other such that one electrode among the glass electrode and the gripper electrode overlaps an entire area of the other electrode; and
arranging the glass electrode and the gripper electrode such entire areas of the glass electrode and the gripper electrode having the same polarity overlap each other.
